(19) United States
(12) Patent Application Publication
(10) Pub. No.: US 2023/0249582 A1
(43) Pub. Date: Aug. 10, 2023

(54) MODEL UPDATE DEVICE, METHOD OF UPDATING MODEL, AND NON-TRANSITORY COMPUTER-READABLE MEDIUM STORING MODEL UPDATE PROGRAM

(71) Applicant: TOYOTA JIDOSHA KABUSHIKI KAISHA, Toyota-shi (JP)

(72) Inventor: Nobuyasu HAGA, Seto-shi (JP)

(73) Assignee: TOYOTA JIDOSHA KABUSHIKI KAISHA, Toyota-shi (JP)

(21) Appl. No.: 18/063,768

(22) Filed: Dec. 9, 2022

(30) Foreign Application Priority Data
Feb. 4, 2022 (JP) 2022-016704

(51) Int. Cl. B60L 58/16; B60L 53/53

(52) U.S. Cl. CPC B60L 58/16; B60L 53/53

(57) ABSTRACT

A model update device, including: a memory; and a processor coupled to the memory, the processor being configured to: for each of plural targets, input information, regarding a state quantity of a battery, to a learned model and acquire a degradation state for a predetermined period; and in a case in which a state, in which the input state quantity satisfies a first criterion determined relative to the state quantity and in which the degradation state satisfies a second criterion determined relative to the degradation quantity, is present at least a predetermined number of times, update the learned model using the information regarding the state quantity that was input to the learned model.

### CROSS-REFERENCE TO RELATED APPLICATION

This application claims priority under 35 USC 119 from Japanese Patent Application No. 2022-016704, filed on Feb. 4, 2022, the disclosure of which is incorporated by reference herein.

### BACKGROUND

### Technical Field

The present disclosure relates to a model update device, a method of updating a model, and a non-transitory computer-readable medium storing a model update program.

### Related Art

Japanese Patent Application Laid-open (JP-A) No. 2020-148560 discloses a technique for improving prediction accuracy when predicting the remaining life of a vehicle battery. In this technique, a prediction model is acquired based on learning data including time series data of a degradation index and a remaining life at a past predetermined point in time of a vehicle battery for learning that has reached the end of its service life.

The conventional technique describes a technique relating to predicting a degradation state of a battery using a prediction model that has learned using learning data. However, when an attempt is made to collect comprehensive learning data, it takes time to provide a diagnostic system employing a prediction model. Moreover, in a case in which comprehensive learning data is acquired in a stepwise manner and the prediction model is updated, the timing at which the prediction model is updated needs to be considered.

### SUMMARY

The present disclosure provides a model update device, a method of updating a model, and a non-transitory computer-readable medium storing a model update program, that may enable a model to be updated at an appropriate timing in accordance with the model.

A first aspect of the present disclosure is a model update device, including: an acquisition unit configured to, for each of a plurality of targets, input information, regarding a state quantity of a battery to a learned model and acquire a degradation state for a predetermined period; and an update unit configured to, in a case in which a state, in which the input state quantity satisfies a first criterion determined relative to the state quantity and in which the degradation state satisfies a second criterion determined relative to the degradation quantity, is present at least a predetermined number of times, update the learned model using the information regarding the state quantity that was input to the learned model.

The model update device of the first aspect updates a model in a case in which the input state quantity and the acquired degradation state satisfy the criteria. This may enable the model to be updated at an appropriate timing.

In a second aspect of the present disclosure, in the above first aspect, the degradation state acquired by the acquisition unit may be predicted as a probability value of degradation in the period, the state in which the second criterion is satisfied may be one of a first state in which the probability value of the degradation state is at least a first threshold value indicating that a degradation pattern is included and is less than a second threshold value determined as a threshold value for which a degree of degradation is higher than for the first threshold value, or a second state in which the probability value of the degradation state is less than the first threshold value, the acquisition unit may acquire respective degradation states for respective information regarding the state quantity obtained from the plurality of targets, and the update unit may determine whether the first state or the second state is present for each of the respective degradation states, and may differentiate a method of updating the learned model between a first case in which a number of times representing the first state is at least a predetermined number of times and a second case in which a number of times representing the second state is at least a predetermined number of times.

According to the model update device of the second aspect, the model may be updated using a different model update method depending on whether the degradation state is the first state or the second state.

In a third aspect of the present disclosure, in the first aspect or the second aspect, the learned model may be updated in a case in which the degradation state satisfies the second criterion, in a case in which there is a determination that a degradation state, measured by a different measurement device from a device that acquired the information regarding the state quantity of the battery, has degraded, even if the input state quantity is not a state quantity that satisfies the first criterion.

According to the model update device of the third aspect, even in a case in which the input battery state quantity does not meet the criteria for updating the model, in a case in which it is determined by other measurement means that the degradation state has degraded, it may be treated as an update target.

In a fourth aspect of the present disclosure, in the above-described aspects, each of a predetermined short-term, medium-term and long-term period may be set as the period; the degradation state acquired by the acquisition unit may be predicted as a probability value of degradation in each of the periods in the learned model; and the update unit may determine whether or not the degradation state in the short-term period is a state that satisfies the second criterion.

According to the model update device of the fourth aspect, the model may be updated by determining the degradation state of the state quantity of the battery acquired over a short-term period.

A fifth aspect of the present disclosure is a method of updating a model, the method including, by a processor: for each of a plurality of targets, inputting information, regarding a state quantity of a battery, to a learned model and acquiring a degradation state for a predetermined period; and in a case in which a state, in which the input state quantity satisfies a first criterion determined relative to the state quantity and in which the degradation state satisfies a second criterion determined relative to the degradation quantity, is present at least a predetermined number of times, updating the learned model using the information regarding the state quantity that was input to the learned model.

In a sixth aspect of the present disclosure, in the fifth aspect, the degradation state may be predicted as a probability value of degradation in the period, the state in which the second criterion is satisfied may be either one of a first state in which the probability value of the degradation state is at least a first threshold value indicating that a degradation pattern is included and is less than a second threshold value determined as a threshold value for which a degree of degradation is higher than for the first threshold value, or a second state in which the probability value of the degradation state is less than the first threshold value, and the processor may: in acquiring the degradation state, acquires the respective degradation states for the respective information regarding the state quantity obtained from the plurality of targets, in updating the learned model, determines whether the first state or the second state is present for each of the degradation states, and differentiates a method of updating the learned model between a first case in which a number of times representing the first state is at least a predetermined number of times and a second case in which a number of times representing the second state is at least a predetermined number of times.

A seventh aspect of the present disclosure is a non-transitory computer-readable medium storing a model update program executable by a computer to perform processing, the processing comprising: for each of plural targets, inputting information, regarding a state quantity of a battery, to a learned model and acquiring a degradation state for a predetermined period; and in a case in which a state, in which the input state quantity satisfies a first criterion determined relative to the state quantity and in which the degradation state satisfies a second criterion determined relative to the degradation quantity, is present at least a predetermined number of times, updating the learned model using the information regarding the state quantity that was input to the learned model.

According to the above-described aspects, a model update device, a method of updating a model, and a non-transitory computer-readable medium storing a model update program, enable a model to be updated at an appropriate timing in accordance with the model.

### BRIEF DESCRIPTION OF THE DRAWINGS

Exemplary embodiments will be described in detail based on the following figures, wherein:

FIG. 1 is a diagram illustrating an example of learning a model and determination using a learned model;

FIG. 2 is a diagram illustrating a schematic configuration of a model update system according to an exemplary embodiment;

FIG. 3 is a block diagram illustrating a hardware configuration of a vehicle of an exemplary embodiment;

FIG. 4 is a block diagram illustrating a hardware configuration of a center server of an exemplary embodiment;

FIG. 5 is a block diagram illustrating a functional configuration of a center server of an exemplary embodiment;

FIG. 6 is a flowchart illustrating a flow of model update processing executed by a center server of an exemplary embodiment;

FIG. 7A is a diagram illustrating an example of application of a validity determination threshold value corresponding to a type of state quantity;

FIG. 7B is a diagram illustrating an example of application of a validity determination threshold value corresponding to a type of state quantity;

FIG. 8 is a flowchart illustrating a flow of updating in a first case;

FIG. 9 is a flowchart illustrating a flow of updating in a second case; and

FIG. 10 is an example of a case in which similar portions of learning data are replaced.

### DETAILED DESCRIPTION

In techniques for estimating degradation of an auxiliary battery (hereafter simply referred to as a battery) in a hybrid system, machine learning using a large amount of learning data enables the robustness of the model to be guaranteed. However, it takes several years to accumulate learning data for learning highly accurate models, and collection requires a certain period of time. This requires that the service is started before sufficient learning data has been accumulated, and the model is updated as the amount of learning data increases. In the present exemplary embodiment, a technique is proposed in which a determination is made as to whether or not the state quantity of an input is a pattern considered in a learned model, and then updating is performed. This enables the model to be updated at an appropriate timing in accordance with the learned model, without performing analysis of newly collected learning data.

Examples of a model and input/output applied to the present exemplary embodiment are described below. The inputs to the model are state quantities of the battery (such as resistance, voltage, and temperature), the model is a neural network such as a CNN, and the output of the model is the likelihood of degradation within a predetermined period, or the likelihood of not degrading within a predetermined period.

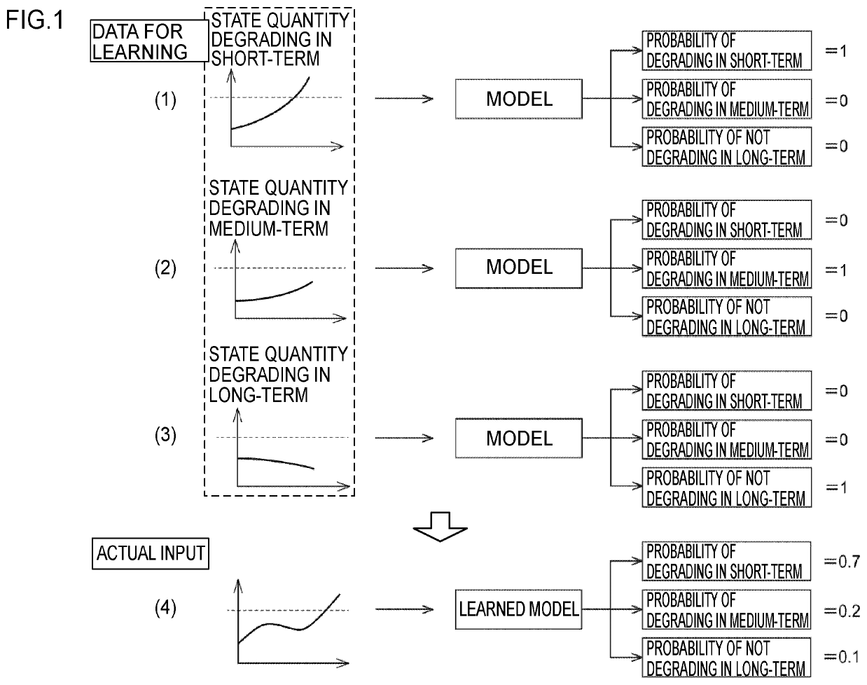

FIG. 1 is a diagram illustrating an example of learning a model and determination using a learned model. In a case in which a map is generated by machine learning, learning data to be input, a probability value to be output, and the like are designated, and a numerical constant map is automatically generated in the model. The numerical constant map maps the input state quantity to a pattern that degrades in the short term, a pattern that degrades in the medium term, and a pattern that does not degrade in the long term, and the output of the model is the probability values of the respective patterns. It is assumed that the respective periods are, for example, a short-term period of 1 month to 2 months, a medium-term period of 3 months to 4 months, or a long-term period of approximately six months. The learning data learns the model by specifying a probability value of a corresponding period as 1 and a probability value of a non-corresponding period as 0 with respect to a state quantity of a battery used as an input. In FIG. 1, the vertical axis of the graph of input of learning data is the value of the state quantity, and the horizontal axis is the time at which the value of the state quantity was acquired. For example, in (1), this is a state quantity in which an input degrades in the short term, and the likelihood of the output degrading in the short term is designated as 1, while the other cases are designated as 0. The state quantity of the input battery and the probability value of the output are the teacher data. The same applies to a case in which degradation has occurred in the medium term in (2) and a case in which long-term degradation has not occurred in (3). (4) is an example of a degradation determination using a learned model, and the state quantity of the battery that is used for actual input is used as an input to the learned model, and determination results based on respective probability values are output together with the respective probability values for the respective periods (respective patterns). As the determination results, a determination result for short-term degradation, a determination result for medium-term degradation, a determination result for long-term non-degradation, and/or a determination result for none of these, are output. The respective probability values are calculated from the learned model based on which pattern of teacher data the input is similar to. In the present exemplary embodiment, it is determined whether or not the learning of the learned model is appropriate by using an output of a probability value of a degradation state in the short term (hereafter also referred to as a short-term degradation probability) from among the respective probability values configuring the output of the learned model, to determine the degradation state.

In the determination of a degradation state, a learned determination threshold value that defines a threshold value indicating that a degradation pattern is included, and a degradation determination threshold value that is defined as a threshold value with a higher degree of degradation than the learned determination threshold value, are used as threshold values for determination of a short-term degradation probability. The threshold value determination is performed by providing a validity determination threshold value for determining whether or not short-term degradation is appropriate, with regard also to the state quantity of the battery that is used as an actual input. The respective threshold values may define threshold values that are set in advance by experimentation or the like. For example, a threshold value in a case in which degradation determination is performed on an output of a learned model, or a criterion value that is higher than this threshold value, is set as the degradation determination threshold value. Namely, in a case in which the output does not exceed the degradation determination threshold value with respect to an input for which short-term degradation is appropriate, updating of the model is required. Moreover, if the learned determination threshold value has been exceeded, at least the pattern of degradation has been learned, and if it has not been exceeded, the pattern of degradation has not been learned in regard to the state quantity of the battery used as the actual input.

The degradation state is designated as a first state in a case in which the learned determination threshold value the short-term degradation probability<the degradation determination threshold value, while the degradation state is designated as a second state in a case in which the short-term degradation probability<the learned determination threshold value. The learned determination threshold value is an example of the “first threshold value” of the technique of the present disclosure, and the degradation determination threshold value is an example of the “second threshold value” of the technique of the present disclosure.

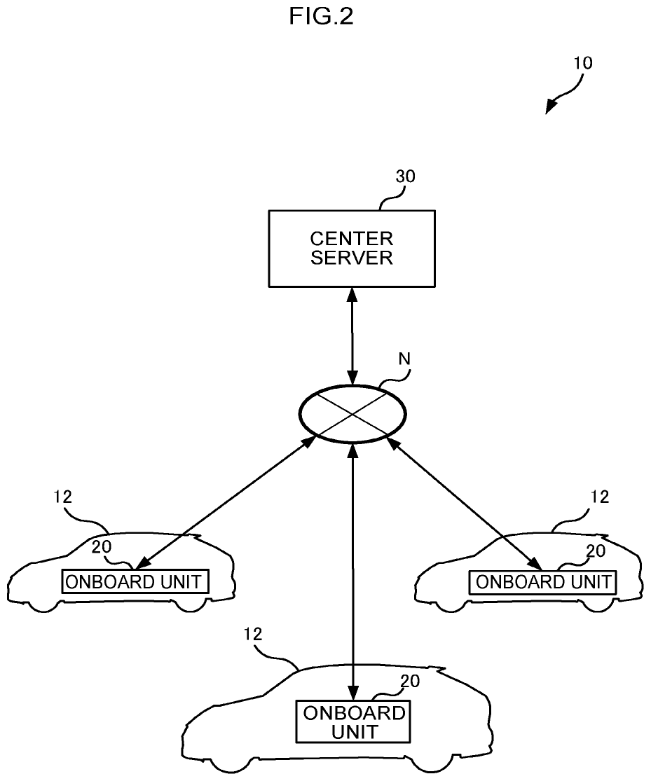

As illustrated in FIG. 2, a model update system 10 of an exemplary embodiment of the present invention includes plural vehicles 12 and a center server 30 serving as a model update device. An onboard unit 20 is installed in each vehicle 12. The onboard unit 20 and the center server 30 are connected to each other via a network N. Although FIG. 2 illustrates three vehicles 12 and onboard units 20 relative to the center server 30, the number of the plural vehicles 12 and the onboard units 20 is not limited to this, and as many vehicles 12 and onboard units 20 are included as are required for model update processing. The center server 30 is installed, for example, at a manufacturer who manufactures the vehicle 12 or at a car dealer affiliated with the manufacturer. Although explanation follows regarding an example of a case in which a vehicle is the target object installed with a battery, other moving objects and targets may be applied as long as the target object is one that is installed with a battery. The plural vehicles 12 are an example of the “plurality of targets” of the technique of the present disclosure.

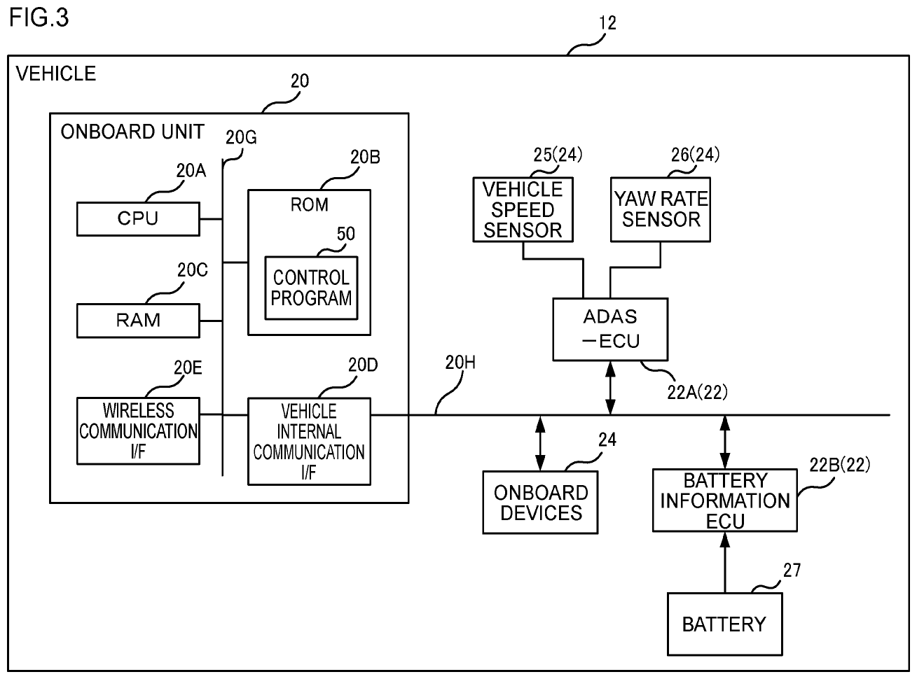

As illustrated in FIG. 3, the vehicle 12 according to the present exemplary embodiment includes an onboard unit 20, plural electronic control units (ECUs) 22, plural onboard devices 24, and an auxiliary battery 27. For convenience of explanation, the reference numeral for the battery 27 is omitted unless specifically described as hardware.

The onboard unit 20 includes a central processing unit (CPU) 20A, read only memory (ROM) 20B, random access memory (RAM) 20C, a vehicle internal communication interface (I/F) 20D, and a wireless communication I/F 20E. The CPU 20A, the ROM 20B, the RAM 20C, the vehicle internal communication I/F 20D, and the wireless communication I/F 20E are connected so as to be capable of communicating with each other via an internal bus 20G.

The CPU 20A is a central processing unit and executes various programs and controls various sections. Namely, the CPU 20A reads a program from the ROM 20B, and executes the program using the RAM 20C as a workspace.

The ROM 20B stores various programs and various data. The ROM 20B of the present exemplary embodiment collects vehicle information relating to states and control of the vehicle 12 from the ECU 22, and moreover, stores a control program 50 that permits or restricts the use of functionality, or the application of equipment, of the vehicle 12. Further, the ROM 20B stores historical information, which is backup data for vehicle information and battery information. The RAM 20C serves as a workspace for temporarily storing programs and data.

The vehicle internal communication I/F 20D is an interface for connecting to the respective ECUs 22. A communication standard based on the CAN protocol is used for the interface. The vehicle internal communication I/F 20D is connected to an external bus 20H.

The wireless communication I/F 20E is a wireless communication module for communicating with the center server 30. For example, a communication standard such as 5G, LTE, Wi-Fi (registered trademark) or the like is used for the wireless communication module. The wireless communication I/F 20E is connected to the network N.

The ECU 22 includes at least an advanced driver assistance system (ADAS)-ECU 22A and a battery information ECU 22B. Although not illustrated in the drawings for convenience of explanation, the ECU 22 provides functionality for performing steering control, brake control, engine control, information system control including the car navigation system and audio, and the like.

The ADAS-ECU 22A performs overall control of the advanced driving assistance system. The ADAS-ECU 22A is connected to a vehicle speed sensor 25 and a yaw rate sensor 26 configuring an onboard device 24.

The onboard devices 24 also include steering angle sensors, brake actuators, throttle actuators, and other sensors as devices required to implement the functionality of the central ECU 20.

The battery information ECU 22B measures the state quantity of the battery 27 over time, and stores this as battery information in the ROM 20B. The battery information stored in the ROM 20B is periodically collected by the center server 30.

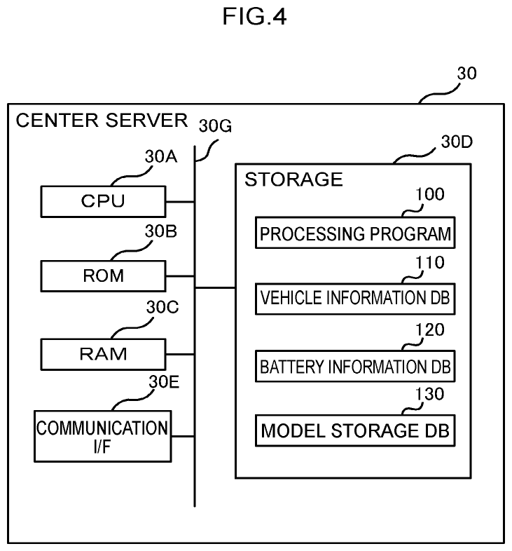

As illustrated in FIG. 4, the center server 30 includes a CPU 30A, a ROM 30B, a RAM 30C, a storage 30D, and a communication I/F 30E. The CPU 30A, the ROM 30B, the RAM 30C, the storage 30D, and the communication I/F 30E are connected so as to be capable of communicating with each other via an internal bus 30G. Functions of the CPU 30A, the ROM 30B, the RAM 30C, and the communication I/F 30E are the same as those of the CPU 20A, the ROM 20B, the RAM 20C, and the wireless communication I/F 20E of the onboard unit 20 described above. The communication I/F 30E may perform wired communication.

The storage 30D, serving as memory, is configured by a hard disk drive (HDD) or a solid state drive (SSD), and stores various programs and various data. The storage 30D of the present exemplary embodiment stores a processing program 100, a vehicle information database (DB) 110, a battery information DB 120, and a model storage DB 130. The ROM 30B may store the processing program 100, the vehicle information DB 110, the battery information DB 120, and a model storage DB 130.

The processing program 100, serving as a model update program, is a program for controlling model updating in the center server 30. Together with execution of the processing program 100, the center server 30 executes model update processing. In the model update processing, information from the vehicle information DB 110, the battery information DB 120, and the model storage DB 130 is read and executed as appropriate.

The vehicle information DB 110 holds vehicle information acquired from the vehicle 12. The vehicle information includes, for example, information relating to driving operation and travel, such as vehicle speed, acceleration, yaw rate, steering angle, accelerator position, brake pedal depression force, and stroke.

The battery information DB 120 stores battery information collected from each vehicle 12. Moreover, the learned determination threshold value, the degradation determination threshold value, and the validity determination threshold value are stored in the battery information DB 120.

The model storage DB 130 stores a learned model. As described above, the learned model is learned so as to use battery information as an input, estimate the probability value for each period as an output, and output a determination result. Further, the model storage DB 130 stores the learning data used to learn the learned models. The learning data includes respective sets of a state quantity of a battery serving as an input and a probability value of a period corresponding to the input.

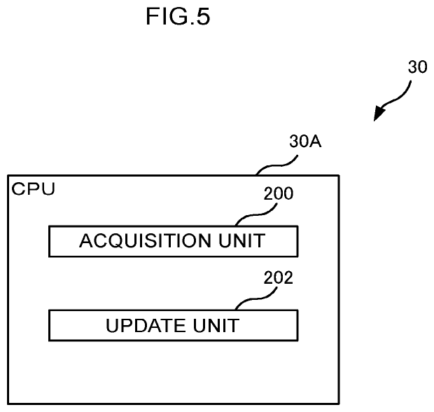

As illustrated in FIG. 5, in the center server 30 of the present exemplary embodiment, the CPU 30A functions as an acquisition unit 200 and an update unit 202 by executing the processing program 100.

The acquisition unit 200 inputs the battery information to the learned model, and acquires a degradation state as a probability value of degradation for each of the short-term, medium-term, and long-term periods. The degradation state is acquired for each of the battery states of the plural vehicles 12.

The update unit 202 performs determination using the short-term degradation state probability value (short-term degradation probability) acquired by the acquisition section 200 and the input battery information. The update unit 202 determines whether or not the degradation state is the first state or the second state, and differentiates the learned model update method between a first case in which the number of times that the first state is represented is equal to or greater than a predetermined number of times and a second case in which the number of times that the second state is represented is equal to or greater than a predetermined number of times. In the first case, it is assumed that a portion of the learning data is similar to the input state quantity pattern. In the second case, it is assumed that the input state quantity pattern is not included in the learning data. Specific details of the determination and the update method are described below.

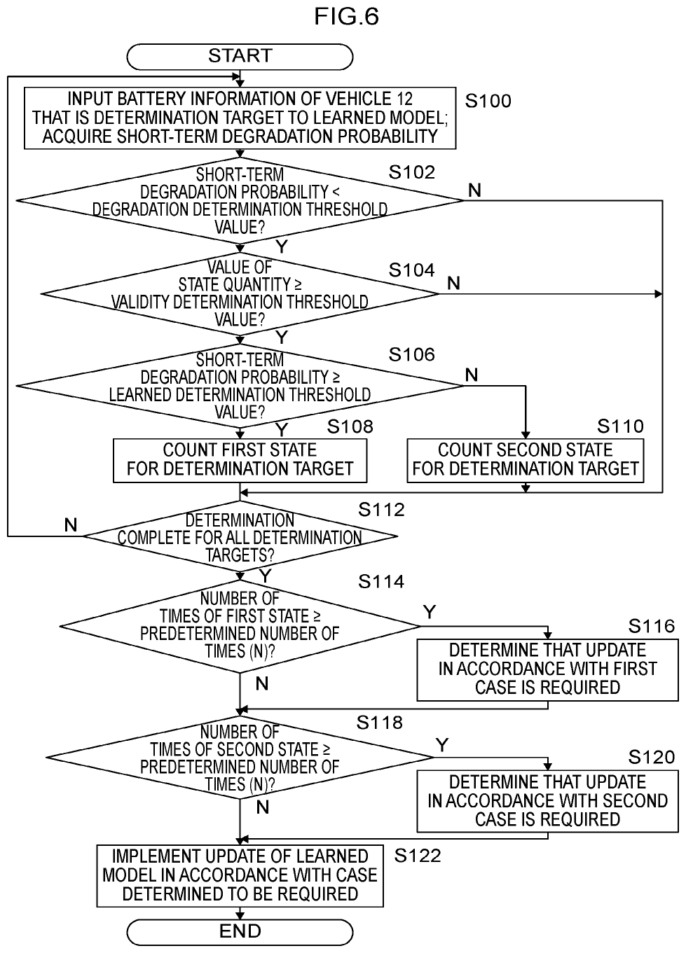

Explanation follows regarding a flow of model update processing executed by the model update system 10 of the present exemplary embodiment, with reference to the flowchart of FIG. 6. The processing performed at the center server 30 is executed by the CPU 30A functioning as the various units of the center server 30.

At step S100, the CPU 30A inputs the battery information of the vehicle 12 serving as the determination target to the learned model, and acquires a short-term degradation probability.

At step S102, the CPU 30A determines whether or not the acquired short-term degradation probability is lower than a degradation determination threshold value (short-term degradation probability<degradation determination threshold value). In a case in which it is lower than the degradation determination threshold value, the processing transitions to step S104, while in a case in which the value is not lower than the degradation determination threshold value, the processing transitions to step S112.

At step S104, the CPU 30A determines whether or not the value of the state quantity of the battery in the input battery information is equal to or greater than a validity determination threshold value (value of state quantity validity determination threshold value). In a case in which the value is equal to or larger than the validity determination threshold value, the processing transitions to step S106, while in a case in which the value is not equal to or larger than the validity determination threshold value, the processing transitions to step S112.

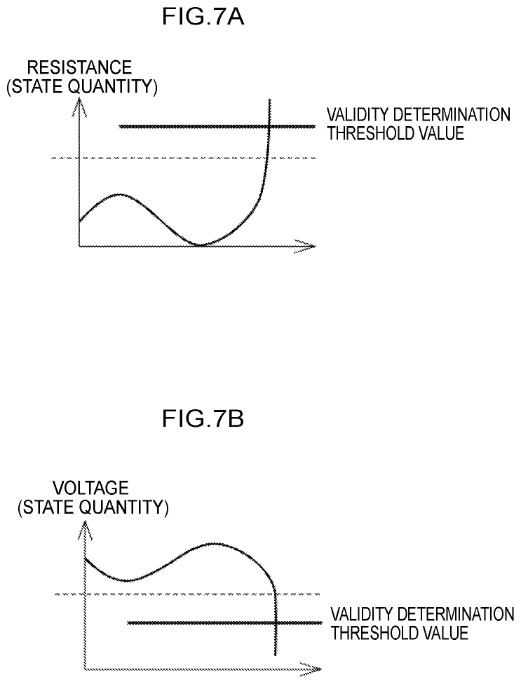

The direction of the inequality symbol indicating whether to set the value to no more than or no less than the validity determination threshold value is variable depending on the type of state quantity. FIG. 7A and FIG. 7B show examples of application of the validity determination threshold value according to the type of state quantity. The vertical axis of FIG. 7A and FIG. 7B is the value of the state quantity, and the horizontal axis is the time at which the value of the state quantity was acquired. As illustrated in FIG. 7A, in a case in which the state quantity is a resistance, the value is set to be equal to or larger than the validity determination threshold value in order to indicate that the value has degraded as the value increases. As illustrated in FIG. 7B, in a case in which the state quantity is a voltage, it is set to be equal to or lower than the validity determination threshold value in order to indicate that the value has degraded as it decreases. A case in which the value of the state quantity satisfies a criterion for a validity determination threshold value is an example of “a case of a state quantity that satisfies a first criterion” in the technique of the present disclosure.

At step S106, the CPU 30A determines whether or not the short-term degradation probability is greater than or equal to the learned determination threshold value (short-term degradation probability learned determination threshold value). In a case in which it is equal to or greater than the learned determination threshold value, the processing transitions to step S108, while in a case in which it is not equal to or greater than the learned determination threshold value, the processing transitions to step S110.

At step S108, the CPU 30A assumes that the battery state quantity of the vehicle 12 serving as the determination target is the first state, and counts this as the first state.

At step S110, the CPU 30A assumes that the battery state quantity of the vehicle 12 serving as the determination target is the second state, and counts this as the second state.

At step S112, the CPU 30A determines whether or not the determination has been completed for all the vehicles 12. In a case in which the determination has been completed, the processing transitions to step S114, and in a case in which the determination has not been completed, the processing returns to step S100, and the next determination target vehicle 12 is selected and the processing repeated.

At step S114, the CPU 30A determines whether or not the number of counted first states is equal to or greater than a predetermined number (N). In a case in which it is determined that the number is the predetermined number of times or more, the processing transitions to step S116, and in a case in which it is determined that the number is not equal to or more than the predetermined number of times, updating of the first case is not required, and the processing transitions to step S118. The number of times N may be, for example, a number of times that is 10% of the total number of vehicles 12 serving as determination targets.

At step S116, the CPU 30A determines that an update according to the first case is required.

At step S118, the CPU 30A determines whether or not the number of counted second states is equal to or greater than a predetermined number (N). In a case in which it is determined that the number is the predetermined number of times or more, the processing transitions to step S120, and in a case in which it is determined that the number is not equal to or more than the predetermined number of times, updating of the second case is not required, and the processing transitions to step S122. The number of times N may be, for example, a number of times that is 10% of the total number of vehicles 12 serving as determination targets.

A case in which the number of times of the first state is equal to or greater than the predetermined number of times at step S114, or a case in which the number of times of the second state is equal to or greater than the predetermined number of times at step S118, is an example of “a case of a state quantity that satisfies a second criterion” in the technique of the present disclosure.

At step S120, the CPU 30A determines that an update according to the second case is required.

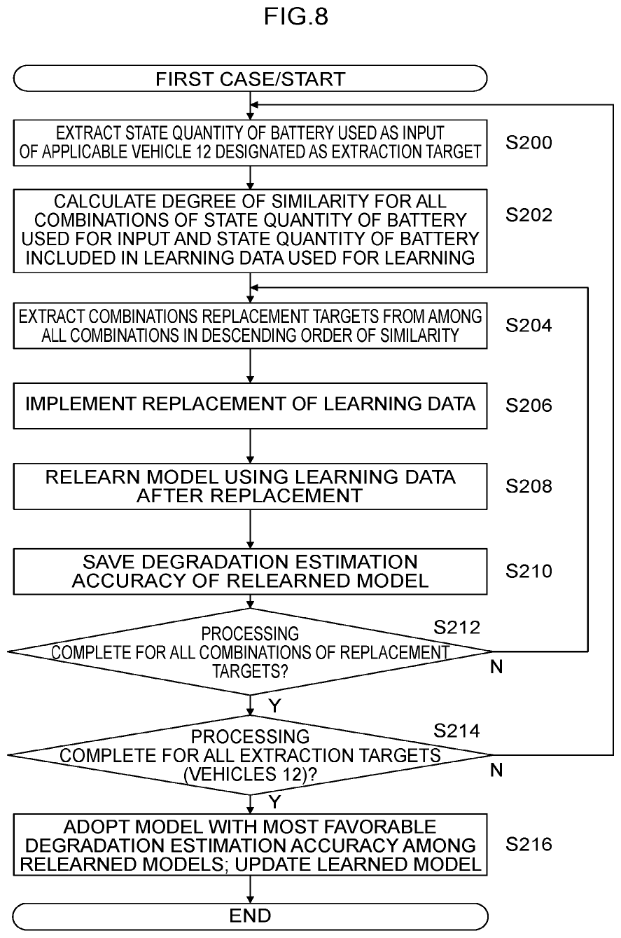

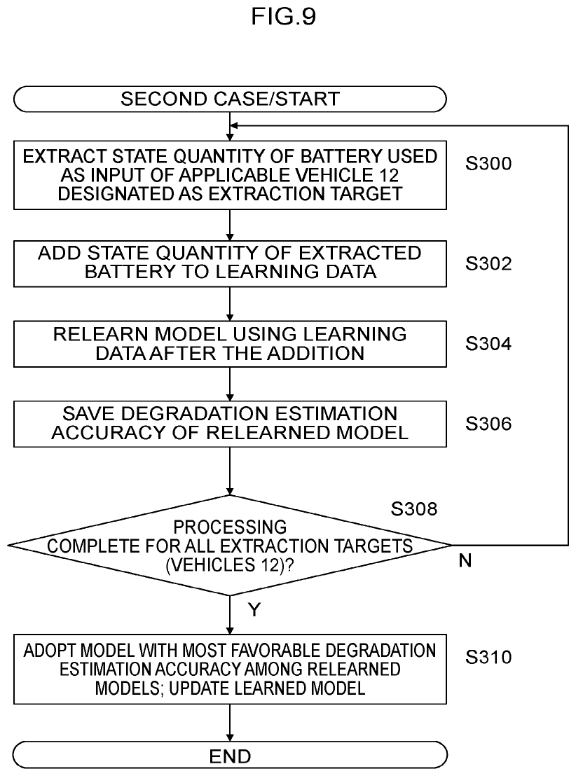

At step S122, the CPU 30A performs an update of the learned model according to the case that has been determined to be required. Explanation follows regarding flows of processing in the respective cases, with reference to the flowchart of FIG. 8 for updating in the first case and the flowchart of FIG. 9 for updating in the second case.

At step S200, the CPU 30A designates the vehicle 12 counted as the first state as an extraction target, and extracts a state quantity of the battery used as the input of the vehicle 12 designated as the extraction target. In a case in which a portion of vehicle information is also used in model learning, the relevant portion of the vehicle information may also be extracted.

At step S202, the CPU 30A calculates the degree of similarity between all combinations of the state quantities of the batteries used for input and the state quantities of the batteries included in the learning data used for learning the learned model.

At step S204, the CPU 30A extracts combinations of replacement targets from all the combinations in descending order of similarity.

At step S206, the CPU 30A replaces the learning data for the replacement target combination. The replacement is performed by replacing a state quantity of the relevant vehicle 12 with a similar portion of the state quantity of the battery included in the learning data, or by modifying similar portions.

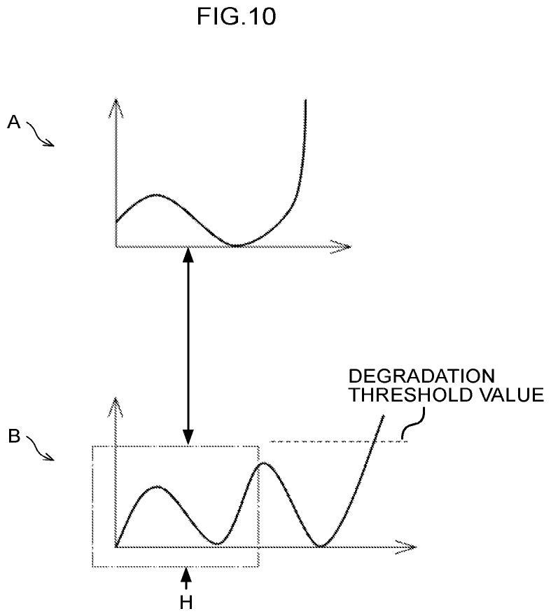

Explanation follows regarding replacement of similar portions. FIG. 10 is an example of a case in which similar portions of learning data are provided as replacement. In the graph of FIG. 10, the vertical axis represents the value of the state quantity, and the horizontal axis represents the time at which the state quantity was acquired. A pattern in a case in which a portion of the state quantity of learning data B is regarded as a waveform pattern H over time is similar to an input A that is actually measured. The learning data B is a state quantity in which a value of a state quantity exceeds a degradation threshold value in a medium-term or long-term pattern H, and similar patterns are included in some of the patterns H. Accordingly, the pattern H portion of the learning data B is deleted, and the input A is added. Alternatively, the learning data B is replaced with the input A.

At step S208, the CPU 30A re-learns the model using the replaced learning data.

At step S210, the CPU 30A saves the degradation estimation accuracy of the re-learned model.

At step S212, the CPU 30A determines whether or not the processing has been completed for combinations of all replacement targets. In a case in which the processing has been completed for all of the replacement targets, the processing transitions to step S214, and in a case in which it is determined that the processing has not been completed for all the replacement targets, the processing returns to step S204, the next replacement target is selected, and the processing is repeated.

At step S214, the CPU 30A determines whether or not the processing has been completed for all extraction targets (vehicles 12). In a case in which it is determined that the processing has been completed for all the extraction targets, the processing transitions to step S216, and in a case in which it is determined that the processing has not been completed for all the extraction targets, the processing returns to step S200, the next extraction target is selected, and the processing is repeated.

At step S216, the CPU 30A adopts a model with the most favorable degradation estimation accuracy among the re-learned models, the learned model in the model storage DB 130 is updated, and the processing is ended.

At step S300, the CPU 30A extracts the state quantity of the battery used for input to the relevant vehicle 12, serving as the extraction target, for the vehicle 12 counted as the first state.

At step S302, the CPU 30A adds the state quantity of the extracted battery to the learning data. Namely, the state quantity designated as the input A in FIG. 10 is added as-is to the learning data.

At step S304, the CPU 30A re-learns the model using the added learning data.

At step S306, the CPU 30A saves the degradation estimation accuracy of the re-learned learned model.

At step S308, the CPU 30A determines whether or not the processing has been completed for all the extraction target vehicles 12. In a case in which it is determined that the processing has been completed for all the extraction targets, the processing transitions to step S310, and in a case in which it is determined that the processing has not been completed for all the extraction targets, the processing returns to step S300, the next extraction target is selected, and the processing is repeated.

At step S310, the CPU 30A adopts the learned model with the most favorable degradation estimation accuracy among the re-learned learned models, the learned model in the model storage DB 130 is updated, and the processing is ended.

In the flowchart of the model update processing illustrated in FIG. 6 and discussed above, in a case in which the value of the state quantity of the battery input does not satisfy the criterion for the validity determination threshold value (in a case in which the state quantity does not satisfy the first criterion), as in step S104, it was assumed that neither the first state nor the second state was counted. However, in a case in which it is determined that the degradation state measured by measuring means such as a tester has degraded, even if the state quantity of the relevant battery does not satisfy the criterion, the learned model may be updated in a case in which the first state or the second state satisfies the condition of the number of times. The measuring means may be a measuring means that is different from the means that acquired the battery information (battery information ECU 22B). In addition to the tester, in a case in which there are other learned models that have been learned differently from the learned models of the present exemplary embodiment, similarly also to cases in which it is determined that a different learned model has degraded, the learned model may be updated in a case in which the first state or the second state satisfies the condition of the number of times.

The center server 30, as a model update device of the present exemplary embodiment, inputs battery information to the learned model at the acquisition unit 200, and acquires degradation states as probability values for degradation during each of the short-term, medium-term, and long-term periods. The center server 30 performs determination using the probability value (short-term degradation probability) of the degradation state in the short term and the input battery information, at the update unit 202. The center server 30 then determines whether or not the degradation state is the first state or the second state, and differentiates the learned model update method between a first case in which the number of times that the first state is represented is equal to or greater than a predetermined number of times and a second case in which the number of times that the second state is represented is equal to or greater than a predetermined number of times. This enables the model to be updated at an appropriate timing in accordance with the model. Moreover, the model can be updated by a different model update method depending on whether the degradation state is the first state or the second state.

The various processing executed by the CPU 20A and the CPU 30A reading and executing software (a program) in the exemplary embodiments described above may be executed by various types of processor other than a CPU. Such processors include programmable logic devices (PLD) that allow circuit configuration to be modified post-manufacture, such as a field-programmable gate array (FPGA), and dedicated electric circuits, these being processors including a circuit configuration custom-designed to execute specific processing, such as an application specific integrated circuit (ASIC). The respective processing described above may be executed by any one of these various types of processor, or by a combination of two or more of the same type or different types of processor (such as plural FPGAs, or a combination of a CPU and an FPGA). The hardware structure of these various types of processors is more specifically an electric circuit combining circuit elements such as semiconductor elements.

In the exemplary embodiments described above, an aspect has been explained in which the respective programs are stored (installed) in advance in a non-transitory recording medium readable by a computer. For example, a program in the onboard unit 20 is stored in advance in the ROM 20B, and the processing program 100 in the center server 30 is stored in advance in the storage 30D. However, the respective programs are not limited thereto, and may be provided in a format recorded on a non-transitory recording medium such as compact disc read only memory (CD-ROM), digital versatile disc read only memory (DVD-ROM), or universal serial bus (USB) memory. Alternatively, the programs may be provided in a format downloadable from an external device over a network.

The flow of processing explained in the exemplary embodiments described above is an example, and unnecessary steps may be deleted, new steps may be added, or the processing order may be rearranged within a range not departing from the spirit of the present invention.

What is claimed is:

1. A model update device, comprising:
a memory; and
a processor coupled to the memory, the processor being configured to:
for each of a plurality of targets, input information, regarding a state quantity of a battery, to a learned model and acquire a degradation state for a predetermined period; and
in a case in which a state, in which the input state quantity satisfies a first criterion determined relative to the state quantity and in which the degradation state satisfies a second criterion determined relative to the degradation quantity, is present at least a predetermined number of times, update the learned model using the information regarding the state quantity that was input to the learned model.

2. The model update device recited in claim 1, wherein:
the degradation state is predicted as a probability value of degradation in the period,
the state in which the second criterion is satisfied is one of a first state in which the probability value of the degradation state is at least a first threshold value indicating that a degradation pattern is included and is less than a second threshold value determined as a threshold value for which a degree of degradation is higher than for the first threshold value, or a second state in which the probability value of the degradation state is less than the first threshold value, and
the processor is configured to:
acquire respective degradation states for respective information regarding the state quantity obtained from the plurality of targets,
determine whether the first state or the second state is present for each of the respective degradation states, and
differentiate a method of updating the learned model between a first case in which a number of times representing the first state is at least a predetermined number of times and a second case in which a number of times representing the second state is at least a predetermined number of times.

3. The model update device recited in claim 1, wherein the processor is configured to update the learned model in a case in which the degradation state satisfies the second criterion, in a case in which there is a determination that a degradation state, measured by a different measurement device from a device that acquired the information regarding the state quantity of the battery, has degraded, even if the input state quantity is not a state quantity that satisfies the first criterion.

4. The model update device recited in claim 1, wherein:
each of a predetermined short-term, medium-term and long-term period are set as the period,
the degradation state is predicted as a probability value of degradation in each of the periods in the learned model, and
the processor is configured to determine whether or not the degradation state in the short-term period is a state that satisfies the second criterion.

5. A method of updating a model, the method comprising, by a processor:
for each of a plurality of targets, inputting information, regarding a state quantity of a battery, to a learned model and acquiring a degradation state for a predetermined period; and
in a case in which a state, in which the input state quantity satisfies a first criterion determined relative to the state quantity and in which the degradation state satisfies a second criterion determined relative to the degradation quantity, is present at least a predetermined number of times, updating the learned model using the information regarding the state quantity that was input to the learned model.

6. The method of updating a model recited in claim 5, wherein:
the degradation state is predicted as a probability value of degradation in the period,
the state in which the second criterion is satisfied is either one of a first state in which the probability value of the degradation state is at least a first threshold value indicating that a degradation pattern is included and is less than a second threshold value determined as a threshold value for which a degree of degradation is higher than for the first threshold value, or a second state in which the probability value of the degradation state is less than the first threshold value, and the processor:
in acquiring the degradation state, acquires the respective degradation states for the respective information regarding the state quantity obtained from the plurality of targets,
in updating the learned model, determines whether the first state or the second state is present for each of the degradation states, and
differentiates a method of updating the learned model between a first case in which a number of times representing the first state is at least a predetermined number of times and a second case in which a number of times representing the second state is at least a predetermined number of times.

7. A non-transitory computer-readable medium storing a model update program executable by a computer to perform processing, the processing comprising:
for each of a plurality of targets, inputting information, regarding a state quantity of a battery, to a learned model and acquiring a degradation state for a predetermined period; and
in a case in which a state, in which the input state quantity satisfies a first criterion determined relative to the state quantity and in which the degradation state satisfies a second criterion determined relative to the degradation quantity, is present at least a predetermined number of times, updating the learned model using the information regarding the state quantity that was input to the learned model.
